(19) United States
(12) Patent Application Publication
(10) Pub. No.: US 2021/0084794 A1
(43) Pub. Date: Mar. 18, 2021

(54) PCM-BASED HEAT SINK STRUCTURE

(71) Applicant: THERMASOL TECHNOLOGY CO., LTD., TAINAN CITY (TW)

(72) Inventor: I-MING LIU, TAINAN CITY (TW)

(21) Appl. No.: 16/822,587

(22) Filed: Mar. 18, 2020

(30) Foreign Application Priority Data
Sep. 18, 2019 (TW) 108133625
Nov. 26, 2019 (CN) 201911174194.6

(51) Int. Cl. H05K 7/20

(52) U.S. Cl. CPC H05K 7/20327; H05K 7/20318; H05K 7/20309

(57) ABSTRACT

A PCM (phase change material)-based heat sink structure includes an evaporation unit, a condensation unit, and a connecting pipe. The evaporation unit has a first space provided with a plurality of spaced first partitions that are integrally formed by an aluminum extrusion process. The first partitions partition the first space into a plurality of first branch passages. The first partitions are formed with a first main passage communicating with each first branch passage. The condensation unit has a second space provided with a plurality of spaced second partitions that are integrally formed by an aluminum extrusion process. The second partitions partition the second space into a plurality of second branch passages. The second partitions are formed with a second main passage communicating with each second branch passage. The connecting pipe is connected between the condensation unit and the evaporation unit to form a circulating heat dissipation loop.

### FIELD OF THE INVENTION

The present invention relates to a heat sink structure that can make a working fluid in full contact with partitions for heat exchange, thereby rapidly, evenly diffusing heat and improving heat dissipation efficiency.

### BACKGROUND OF THE INVENTION

Because electronic products are prone to have a high temperature during operation, the high temperature may affect the efficiency and quality of the entire operation. Therefore, heat needs to be dissipated immediately. There are various heat sink structures to solve the problem of heat dissipation.

For example, Taiwan Utility Model Publication No. M246690 published on Oct. 11, 2004 discloses a phase change material based heat dissipation device, comprising two parallel plates and at least one pipe. Each plate is hollow and has a chamber therein. The inner wall of each plate is provided with a wick structure. A working medium is contained in the chamber. Opposite ends of the pipe are connected to the two plates, respectively. The pipe is hollow and has a passage communicating with the chambers of the plates. The inner wall of the pipe is also provided with a wick structure. However, the inside of the chamber is hollow without any auxiliary heat dissipation structure, so the surface area for heat dissipation is small and the heat dissipation effect is not good.

Taiwan Patent Publication No. 1650520 published on Feb. 11, 2019 discloses a phase change material based evaporator and a phase change material based heat dissipation device. The phase change material based evaporator comprises a main body and a reinforcing plate in the main body. The reinforcing plate partitions an evaporation chamber provided with heat-conducting fins into two spaces. The two spaces are in communication with a coolant outlet. The side wall of the main body is formed with a coolant inlet having a cross-sectional area less than that of the coolant outlet. The phase change material based heat dissipation device includes a condenser having a coolant output pipe and a coolant return pipe connected to the coolant outlet and the coolant inlet of the phase change material based evaporator to form a coolant circulation loop. The coolant circulation loop is filled with a coolant. The reinforcing plate is configured to reinforce the structure of the phase change material based evaporator and to partition the evaporation chamber into two spaces. When the phase change material based evaporator contacts a heat source to evaporate the coolant to be in a gaseous state, the internal pressure in the evaporation chamber increases. In cooperation with the gas pressure difference between the coolant outlet and the coolant inlet that have different cross-sectional areas, the gaseous coolant quickly flows toward the coolant outlet to improve the performance of coolant circulation.

In the above patent, the evaporation chamber is provided with a plurality of spaced heat-conducting fins each bent to be in a wave shape so as to facilitate heat dissipation. However, the heat-conducting fins are manufactured separately and then assembled in the evaporation chamber, which causes complexity and difficulty in manufacture and assembly and also increases man-hours. The top of the casing is provided with a guide end. The guide end has a guide chamber therein. The guide chamber communicates with the evaporation chamber through a port, so as to collect the output of the working fluid. This structure increases the volume of the evaporator. There is a certain gap between every two of the heat-conducting fins. The coolant inlet is a single hole passing through and communicating with the two spaces. As a result, the working fluid (coolant) only flows through the gap between the heat-conducting fins that are close, and the working fluid cannot flow through the gap between the heat-conducting fins that are far away, making the overall heat dissipation efficiency poor. The outside of the condenser is provided with heat dissipation members to increase the surface area for heat dissipation so as to dissipate heat rapidly. However, the inside of the condenser does not have any auxiliary heat dissipation structure. Therefore, the contact area with the working fluid flowing therethrough is relatively small, and the heat exchange efficiency becomes poor. In addition, the overall volume of the heat dissipation device becomes larger, occupying much accommodation space when it is installed to the heat source, so it is not ideal for use. Accordingly, the inventor of the present invention has devoted himself based on his many years of practical experiences to solve these problems.

### SUMMARY OF THE INVENTION

In view of the shortcomings of the prior art, the primary object of the present invention is to provide a PCM (phase change material)-based heat sink structure, comprising an evaporation unit, a condensation unit, and a connecting pipe. The evaporation unit has a sealed first space therein. The first space is provided with a plurality of spaced first partitions that are integrally formed by an aluminum extrusion process. The first partitions partition the first space into a plurality of first branch passages. The first partitions are formed with a first main passage. The first main passage is in communication with each of the first branch passages. The condensation unit and the evaporation unit form a circulating heat dissipation loop. The condensation unit has a sealed second space therein. The second space is provided with a plurality of spaced second partitions that are integrally formed by an aluminum extrusion process. The second partitions partition the second space into a plurality of second branch passages. The second partitions are formed with a second main passage. The second main passage is in communication with each of the second branch passages. An outer periphery of the condensation unit is provided with at least one heat dissipation fin. The connecting pipe includes at least one first pipe and at least one second pipe. The first pipe has a first end passing through the evaporation unit and communicating with the first space and a second end passing through the condensation unit and communicating with the second space. The second pipe has a third end passing through the evaporation unit and communicating with the first space and a fourth end passing through the condensation unit and communicating with the second space.

Preferably, a periphery of the evaporation unit is formed with a first processing port communicating with the first space. The first processing port corresponds in position to middle portions of the first partitions. Through the first processing port, the middle portions of the first partitions are formed with the first main passage by a milling process. The first processing port is sealed with a first shield, thereby sealing the first space.

Preferably, a periphery of the condensation unit is formed with a second processing port communicating with the second space. The second processing port corresponds in position to middle portions of the second partitions. Through the second processing port, the middle portions of the second partitions are formed with the second main passage by a milling process. The second processing port is sealed with a second shield, thereby sealing the second space.

Alternatively, one side of an outer periphery of the evaporation unit, corresponding in position to middle portions of the first partitions, is formed with the first main passage by a drilling process. The first end is in communication with the first main passage.

Preferably, middle portions of the second partitions are formed with the second main passage.

Alternatively, one side of the outer periphery of the condensation unit, corresponding in position to middle portions of the second partitions, is formed with the second main passage by a drilling process. The second end is in communication with the second main passage.

Preferably, the periphery of the evaporation unit is formed with a first opening and a second opening opposite to the first opening. The first opening and the second opening are in communication with the first space. The first opening is sealed with a first cover and the second opening is sealed with a second cover, thereby sealing the first space.

Preferably, the first cover is provided with an injection end. The first space and the second space are exhausted to be in a vacuum state through the injection end and sealed after being filled with a working fluid. The third end passes through the second cover and communicates with the first branch passages.

Preferably, the periphery of the condensation unit is formed with a third opening and a fourth opening opposite to the third opening. The third opening and the fourth opening are in communication with the second space. The third opening is sealed with a third cover and the fourth opening is sealed with a fourth cover, thereby sealing the second space. The second end passes through the fourth cover and communicates with the second branch passages. The fourth end passes through the third cover and communicates with the second branch passages.

Preferably, the first pipe has a total cross-sectional area greater than that of the second pipe.

The above technical features have the following advantages:

1. The plurality of spaced first partitions and the plurality of spaced second partitions are integrally formed by an aluminum extrusion process, respectively. This reduces the process and time of manufacturing and installing the partitions.

2. Utilizing the phase change characteristics of the working fluid, the working fluid can directly flow through the first and second main passages to each of the first and second branch passages, without any dead angle for heat exchange. Therefore, the working fluid is in full contact with the partitions for heat exchange, so as to diffuse heat quickly and improve heat dissipation efficiency, thereby achieving the best heat dissipation function.

3. The working fluid can be directly outputted via the first main passage or the second main passage. There is no need to provide the structure of the guide end and the guide chamber for collecting the working fluid. Therefore, the internal space of the evaporation unit and the condensation unit can be reduced, and the overall volume and weight can be greatly reduced, and the accommodating space when installed to a heat source can be reduced.

4. The outer periphery of the condensation unit is provided with a plurality of heat dissipation fins, thereby increasing the surface area for heat dissipation to enhance the heat dissipation effect and improving the heat exchange efficiency.

### BRIEF DESCRIPTION OF THE DRAWINGS

FIG. 1 is an exploded view of a first embodiment of the present invention;

FIG. 2 is a schematic view of the first embodiment coupled to a heat source of the present invention when in use;

FIG. 3 is a cross-sectional view of the first embodiment formed with a plurality of first branch passages of the present invention;

FIG. 4 is a schematic view of an evaporation unit according to the first embodiment of the present invention;

FIG. 5 is a schematic view of a condensation unit according to the first embodiment of the present invention;

FIG. 6 is a schematic view of a working fluid flowing between the evaporation unit and the condensation unit according to the first embodiment of the present invention;

FIG. 7 is an exploded view of a second embodiment of the present invention;

FIG. 8 is a perspective view of the second embodiment of the present invention;

FIG. 9 is a schematic view of the working fluid flowing between the evaporation unit and the condensation unit according to the second embodiment of the present invention;

FIG. 10 is an exploded view of a third embodiment of the present invention;

FIG. 11 is a perspective view of the third embodiment of the present invention; and

FIG. 12 is a schematic view of the working fluid flowing between the evaporation unit and the condensation unit according to the third embodiment of the present invention.

### DETAILED DESCRIPTION OF THE PREFERRED EMBODIMENTS

Embodiments of the present invention will now be described, by way of example only, with reference to the accompanying drawings.

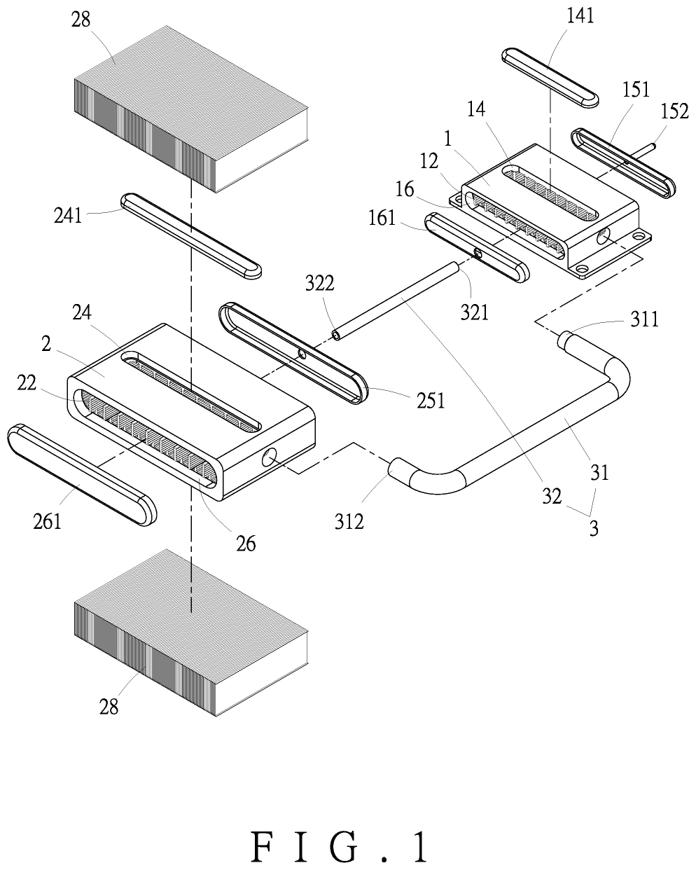

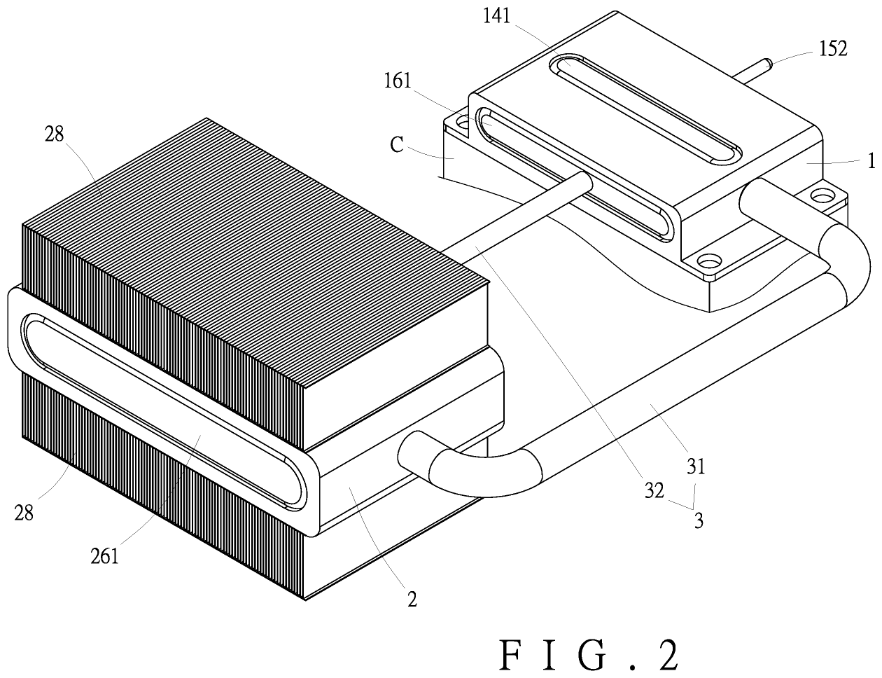

As shown in FIG. 1 and FIG. 2, a first embodiment of the present invention comprises an evaporation unit (1), a condensation unit (2), and a connecting pipe (3).

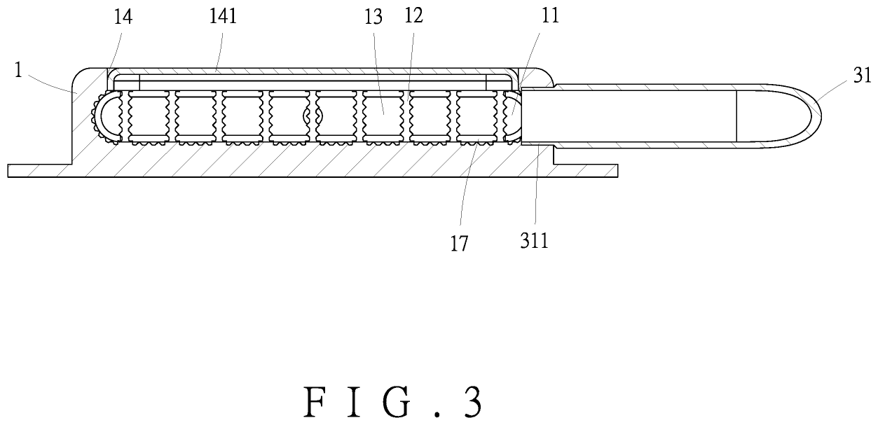

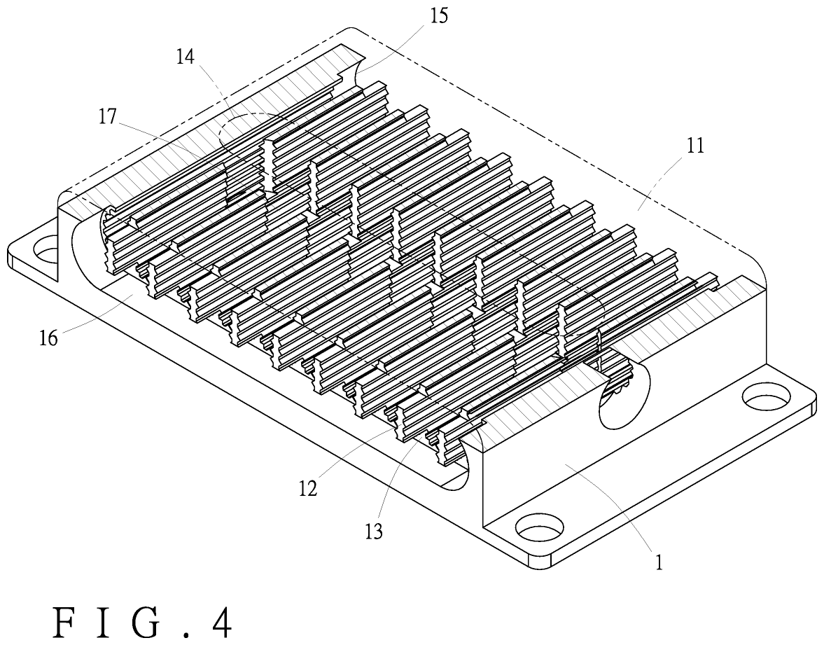

The evaporation unit (1) is configured to be coupled to a heat source (C) for dissipating heat. A first space (11) is defined in the evaporation unit (1), as shown in FIG. 3. The first space (11) is provided with a plurality of spaced first partitions (12) that are integrally formed by an aluminum extrusion process. The first partitions (12) partition the first space (11) into a plurality of first branch passages (13). The periphery of the evaporation unit (1) is formed with a first processing port (14), a first opening (15) and a second opening (16) opposite to the first opening (15), as shown in FIG. 4. The first processing port (14), the first opening (15) and the second opening (16) are in communication with the first space (11). The first processing port (14) corresponds in position to middle portions of the first partitions (12). Through the first processing port (14), the middle portions of the first partitions (12) are formed with a first main passage (17) by a milling process, as shown in FIG. 4. The first main passage (17) is in communication with each of the first branch passages (13). The first processing port (14) is sealed with a first shield (141), the first opening (15) is sealed with a first cover (151), and the second opening (16) is sealed with a second cover (161), thereby sealing the first space (11). The first cover (151) is provided with an injection end (152), so that the first space (11) can be exhausted to be in a vacuum state through the injection end (152) and sealed after being filled with a working fluid. The working fluid is a coolant.

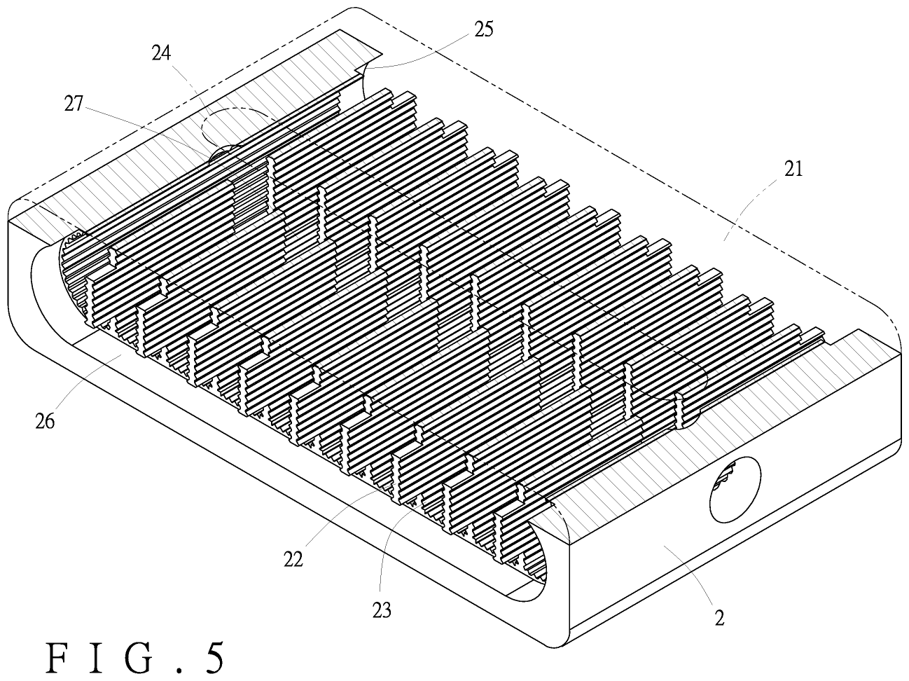

The condensation unit (2) and the evaporation unit (1) form a circulating heat dissipation loop. A second space (21) is defined in the condensation unit (2), as shown in FIG. 5. The second space (21) can be exhausted to be in a vacuum state through the injection end (152). The second space (21) is provided with a plurality of spaced second partitions (22) that are integrally formed by an aluminum extrusion process. The second partitions (22) partition the second space (21) into a plurality of second branch passages (23). The periphery of the condensation unit (2) is formed with a second processing port (24), a third opening (25) and a fourth opening (26) opposite to the third opening (25). The second processing port (24), the third opening (25) and the fourth opening (26) are in communication with the second space (21). The second processing port (24) corresponds in position to middle portions of the second partitions (22). Through the second processing port (24), the middle portions of the second partitions (22) are formed with a second main passage (27) by a milling process. The second main passage (27) is in communication with each of the second branch passages (23). The second processing port (24) is sealed with a second shield (241), the third opening (25) is sealed with a third cover (251), and the fourth opening (26) is sealed with a fourth cover (261), thereby sealing the second space (21). Furthermore, the outer periphery of the condensation unit (2) is provided with upper and lower heat dissipation fins (28).

The connecting pipe (3) is connected between the evaporation unit (1) and the condensation unit (2), thereby circulating the working fluid. The connecting pipe (3) includes at least one first pipe (31) and at least one second pipe (32). The first pipe (31) has a first end (311) passing through the evaporation unit (1) and communicating with the first main passage (17) and a second end (312) passing through the condensation unit (2) and communicating with the second main passage (27). The second pipe (32) has a third end (321) passing through the second cover (161) and communicating with the first branch passages (13) and a fourth end (322) passing through the third cover (251) and communicating with the second branch passages (23). The total cross-sectional area of the first pipe (31) is greater than the total cross-sectional area of the second pipe (32).

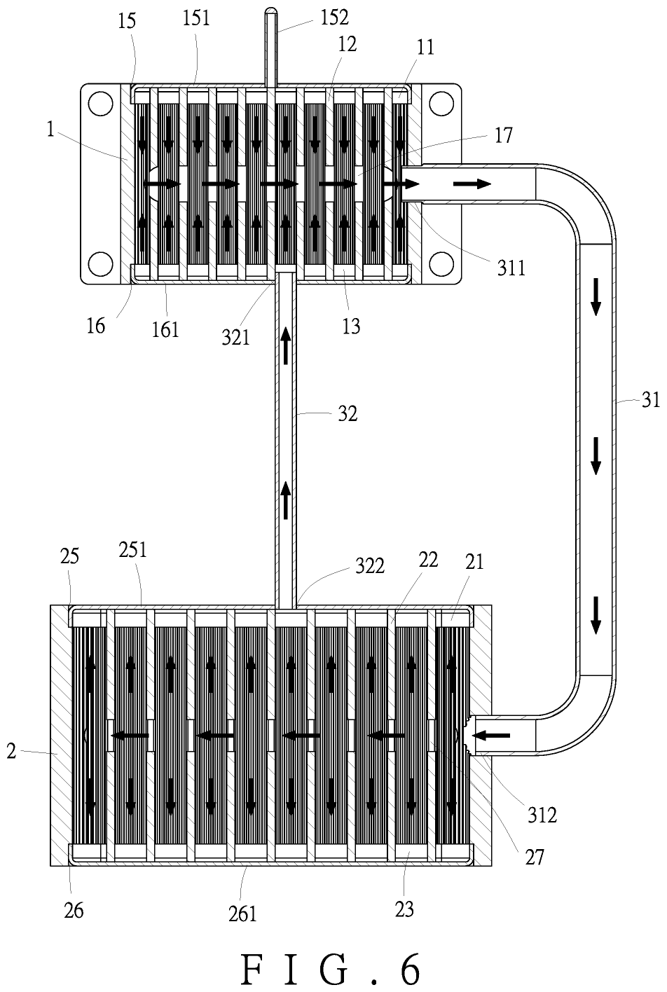

When in use, as shown in FIG. 1, FIG. 2 and FIG. 6, the evaporation unit (1) is fixed to a heat source (C). The heat source (C) may be a cloud server device or a CPU of a computer. The thermal energy generated by the heat source (C) can be conducted to the surface of the evaporation unit (1). The thermal energy received by the evaporation unit (1) can be conducted to each first partition (12) in the first space (11) and accumulated. The working fluid in the first space (11) flows through the first main passage (17) to each of the first branch passages (13), and then the working fluid is in full contact with the thermal energy accumulated by the first partitions (12) to perform heat exchange. After the working fluid receives the thermal energy, it will change from the liquid phase to the gas phase. Since the total cross-sectional area of the first pipe (31) is greater than the total cross-sectional area of the second pipe (32), the working fluid converted into the gas phase generates a pressure difference due to gas expansion and flows through the first pipe (31) having a larger diameter to the second space (21) of the condensation unit (2). The working fluid entering the second space (21) flows through the second main passage (27) to each of the second branch passages (23). Then, the working fluid is in full contact with the relatively low-temperature second partitions (22) to perform heat exchange, so that the working fluid is changed from the gas phase to the liquid phase after the temperature is reduced. After that, the working fluid is circulated back to the first space (11) of the evaporation unit (1) through the second pipe (32) to continue to dissipate heat. After receiving the thermal energy, the second partitions (22) conduct the thermal energy to the heat dissipation fins (28) on the outer periphery of the condensation unit (2) to perform heat exchange with relatively low-temperature outside air, thereby completing the heat dissipation of the heat source (C).

According to the present invention, the plurality of spaced first partitions (12) and the plurality of spaced second partitions (22) are integrally formed by an aluminum extrusion process, respectively. This can reduce the process and time of manufacturing and installing the partitions and can reduce the overall volume of the evaporation unit (1) and the condensation unit (2). Moreover, the working fluid can be directly outputted via the first main passage (17) or the second main passage (27). There is no need to provide the structure of the guide end and the guide chamber for collecting the working fluid, so the overall volume can be greatly reduced. Furthermore, through the phase change characteristics of the working fluid and the first main passage (17) and the second main passage (27) that are in communication with the respective first branch passages (13) and the respective second branch passages (23), the heat exchange can be performed fully, so that heat diffusion can be performed quickly and heat dissipation efficiency can be improved to achieve the best heat dissipation effect.

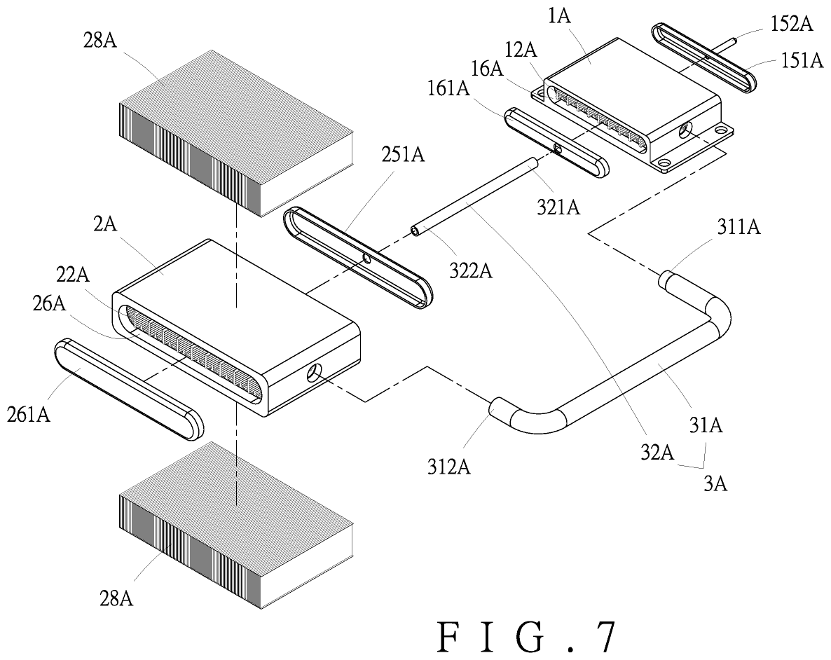

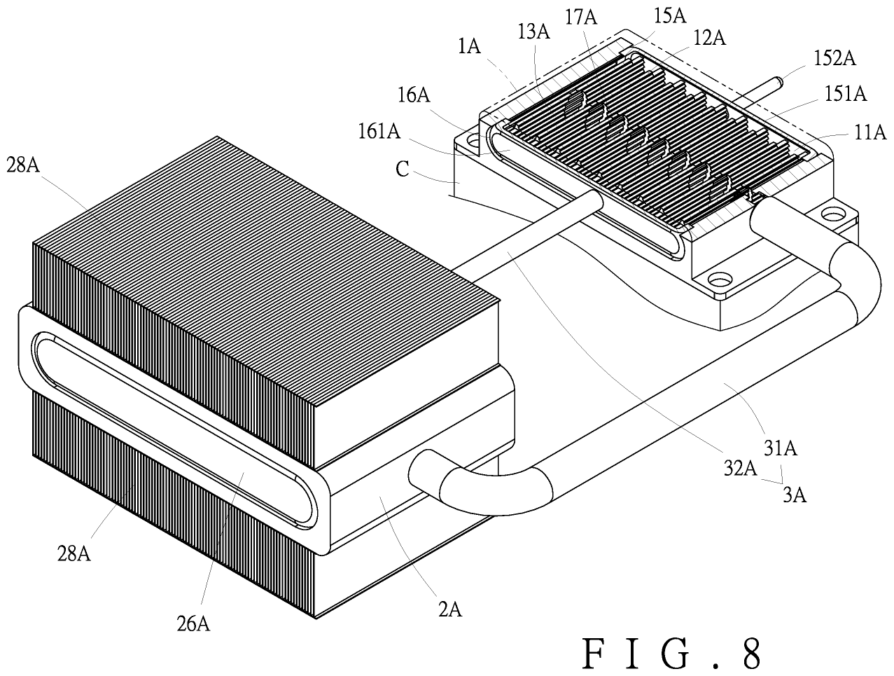

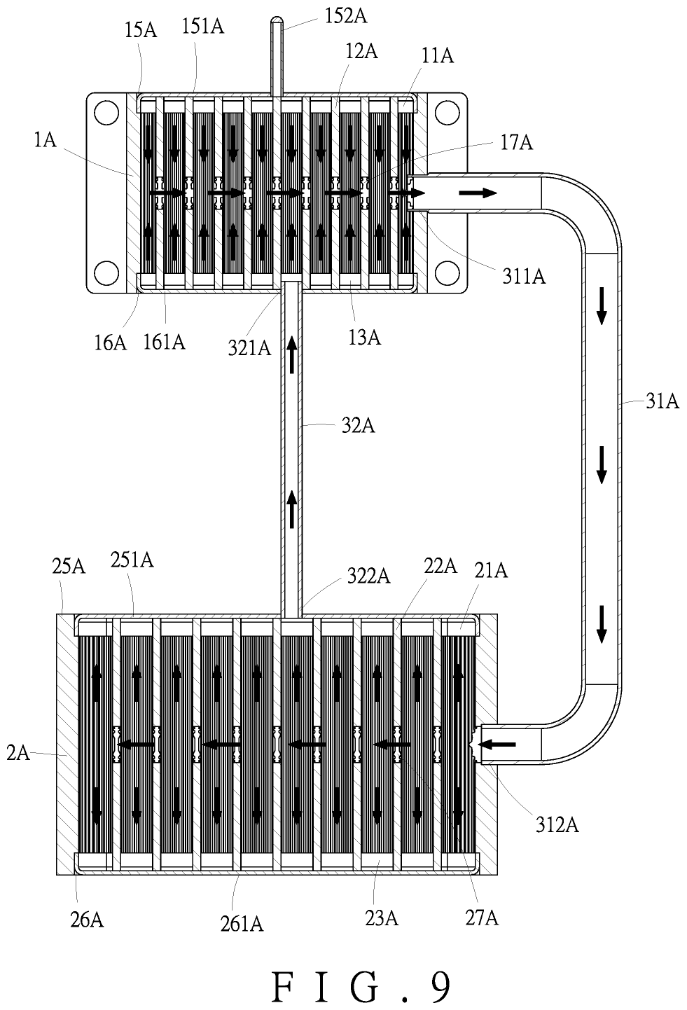

As shown in FIG. 7, FIG. 8 and FIG. 9, a second embodiment of the present invention comprises an evaporation unit (1A), a condensation unit (2A), and a connecting pipe (3A).

The evaporation unit (1A) is configured to be coupled to a heat source (C) for dissipating heat. A first space (11A) is defined in the evaporation unit (1A). The first space (11A) is provided with a plurality of spaced first partitions (12A) that are integrally formed by an aluminum extrusion process. The first partitions (12A) partition the first space (11A) into a plurality of first branch passages (13A). The periphery of the evaporation unit (1A) is formed with a first opening (15A) and a second opening (16A) opposite to the first opening (15A). The first opening (15A) and the second opening (16A) are in communication with the first space (11A). The first opening (15A) is sealed with a first cover (151A), and the second opening (16A) is sealed with a second cover (161A), thereby sealing the first space (11A). The first cover (151A) is provided with an injection end (152A), so that the first space (11A) can be exhausted to be in a vacuum state through the injection end (152A) and sealed after being filled with a working fluid. The working fluid is a coolant. One side of the outer periphery of the evaporation unit (1A), corresponding in position to middle portions of the first partitions (12A), is formed with a first main passage (17A) by a drilling process. The first main passage (17A) is in communication with each of the first branch passages (13A).

The condensation unit (2A) and the evaporation unit (1A) form a circulating heat dissipation loop. A second space (21A) is defined in the condensation unit (2A). The second space (21A) can be exhausted to be in a vacuum state through the injection end (152A). The second space (21A) is provided with a plurality of spaced second partitions (22A) that are integrally formed by an aluminum extrusion process. The second partitions (22A) partition the second space (21A) into a plurality of second branch passages (23A). The periphery of the condensation unit (2A) is formed with a third opening (25A) and a fourth opening (26A) opposite to the third opening (25A). The third opening (25A) and the fourth opening (26A) are in communication with the second space (21A). The third opening (25A) is sealed with a third cover (251A), and the fourth opening (26A) is sealed with a fourth cover (261A), thereby sealing the second space (21A). One side of the outer periphery of the condensation unit (2A), corresponding in position to middle portions of the second partitions (22A), is formed with a second main passage (27A) by a drilling process. The second main passage (27A) is in communication with each of the second branch passages (23A). Furthermore, the outer periphery of the condensation unit (2A) is provided with upper and lower heat dissipation fins (28A).

The connecting pipe (3A) is connected between the evaporation unit (1A) and the condensation unit (2A), thereby circulating the working fluid. The connecting pipe (3A) includes at least one first pipe (31A) and at least one second pipe (32A). The first pipe (31A) has a first end (311A) passing through the evaporation unit (1A) and communicating with the first main passage (17A) and a second end (312A) passing through the condensation unit (2A) and communicating with the second main passage (27A). The second pipe (32A) has a third end (321A) passing through the second cover (161A) and communicating with the first branch passages (13A) and a fourth end (322A) passing through the third cover (251A) and communicating with the second branch passages (23A). The total cross-sectional area of the first pipe (31A) is greater than the total cross-sectional area of the second pipe (32A).

When in use, as shown in FIG. 7, FIG. 8 and FIG. 9, the thermal energy received by the evaporation unit (1A) can be conducted to each first partition (12A) in the first space (11A) and accumulated. The working fluid in the first space (11A) flows through the first main passage (17A) to each of the first branch passages (13A), and the working fluid is in full contact with the thermal energy accumulated by the first partitions (12A) to perform heat exchange. After the working fluid receives the thermal energy, it will change from the liquid phase to the gas phase. The working fluid flows through the first pipe (31A) to the second space (21A) of the condensation unit (2A). The working fluid entering the second space (21A) flows through the second main passage (27A) to each of the second branch passages (23A). Then, the working fluid is in full contact with the relatively low-temperature second partitions (22A) to perform heat exchange, so that the working fluid is changed from the gas phase to the liquid phase after the temperature is reduced. After that, the working fluid is circulated back to the first space (11A) of the evaporation unit (1A) through the second pipe (32A) to continue to dissipate heat. After receiving the thermal energy, the second partitions (22A) conduct the thermal energy to the heat dissipation fins (28A) on the outer periphery of the condensation unit (2A) to perform heat exchange with relatively low-temperature outside air, thereby completing the heat dissipation of the heat source (C).

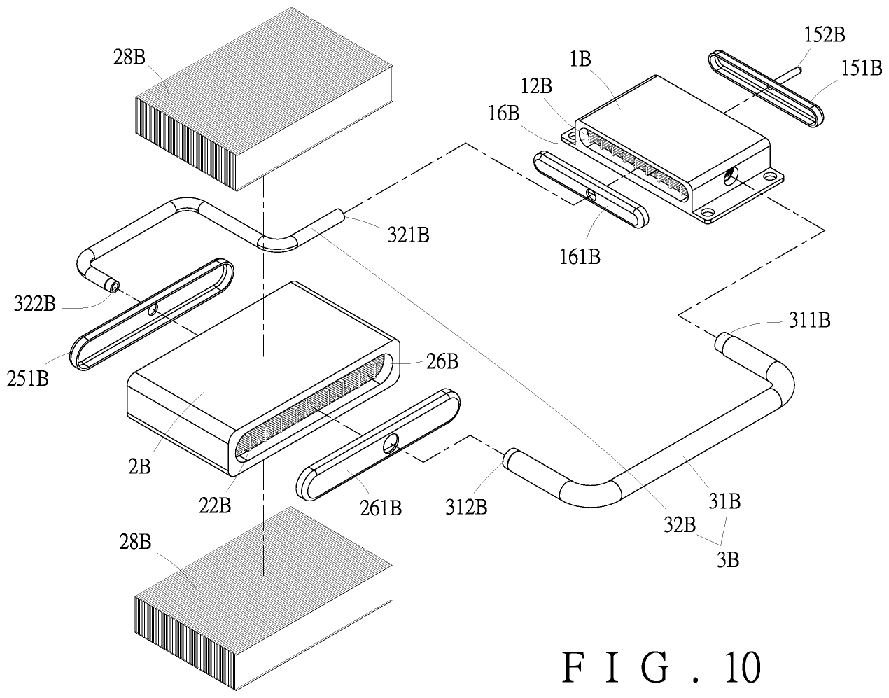

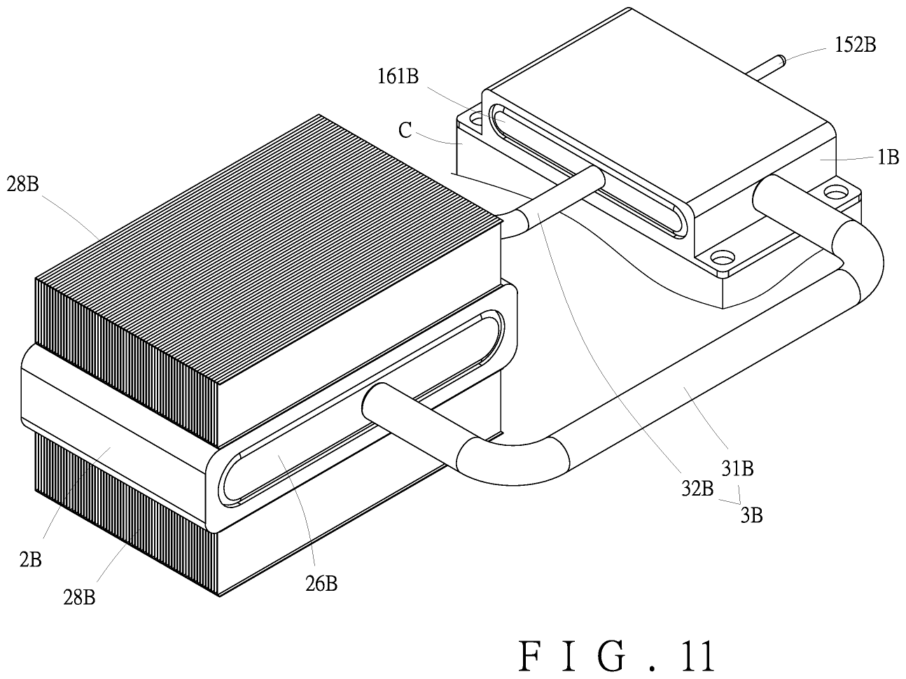

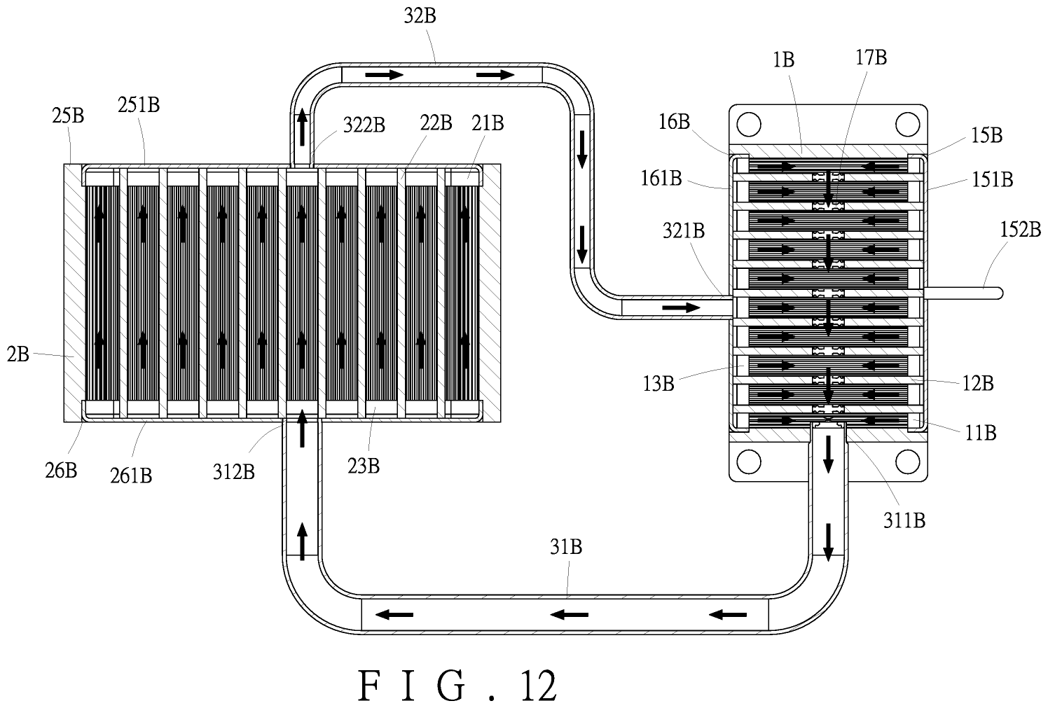

As shown in FIG. 10, FIG. 11 and FIG. 12, a third embodiment of the present invention comprises an evaporation unit (1B), a condensation unit (2B), and a connecting pipe (3B).

The evaporation unit (1B) is configured to be coupled to a heat source (C) for dissipating heat. A first space (11B) is defined in the evaporation unit (1B). The first space (11B) is provided with a plurality of spaced first partitions (12B) that are integrally formed by an aluminum extrusion process. The first partitions (12B) partition the first space (11B) into a plurality of first branch passages (13B). The periphery of the evaporation unit (1B) is formed with a first opening (15B) and a second opening (16B) opposite to the first opening (15B). The first opening (15B) and the second opening (16B) are in communication with the first space (11B). The first opening (15B) is sealed with a first cover (151B), and the second opening (16B) is sealed with a second cover (161B), thereby sealing the first space (11B). The first cover (151B) is provided with an injection end (152B), so that the first space (11B) can be exhausted to be in a vacuum state through the injection end (152B) and sealed after being filled with a working fluid. One side of the outer periphery of the evaporation unit (1B), corresponding in position to middle portions of the first partitions (12B), is formed with a first main passage (17B) by a drilling process. The first main passage (17B) is in communication with each of the first branch passages (13B).

The condensation unit (2B) and the evaporation unit (1B) form a circulating heat dissipation loop. A second space (21B) is defined in the condensation unit (2B). The second space (21B) can be exhausted to be in a vacuum state through the injection end (152B). The second space (21B) is provided with a plurality of spaced second partitions (22B) that are integrally formed by an aluminum extrusion process. The second partitions (22B) partition the second space (21B) into a plurality of second branch passages (23B). The periphery of the condensation unit (2B) is formed with a third opening (25B) and a fourth opening (26B) opposite to the third opening (25B). The third opening (25B) and the fourth opening (26B) are in communication with the second space (21B). The third opening (25B) is sealed with a third cover (251B), and the fourth opening (26B) is sealed with a fourth cover (261B), thereby sealing the second space (21B). Furthermore, the outer periphery of the condensation unit (2B) is provided with upper and lower heat dissipation fins (28B).

The connecting pipe (3B) is connected between the evaporation unit (1B) and the condensation unit (2B), thereby circulating the working fluid. The connecting pipe (3B) includes at least one first pipe (31B) and at least one second pipe (32B). The first pipe (31B) has a first end (311B) passing through the evaporation unit (1B) and communicating with the first main passage (17B) and a second end (312B) passing through the fourth cover (261B) and communicating with the second branch passage (23B). The second pipe (32B) has a third end (321B) passing through the second cover (161B) and communicating with the first branch passages (13B) and a fourth end (322B) passing through the third cover (251B) and communicating with the second branch passages (23B). The total cross-sectional area of the first pipe (31B) is greater than the total cross-sectional area of the second pipe (32B).

When in use, as shown in FIG. 10, FIG. 11 and FIG. 12, the thermal energy received by the evaporation unit (1B) can be conducted to each first partition (12B) in the first space (11B) and accumulated. The working fluid in the first space (11B) is in full contact with the thermal energy accumulated by the first partitions (12B) to perform heat exchange. After the working fluid receives the thermal energy, it will change from the liquid phase to the gas phase. The working fluid flows through the first pipe (31B) to the second space (21B) of the condensation unit (2B). The working fluid entering the second space (21B) is in full contact with the relatively low-temperature second partitions (22B) to perform heat exchange, so that the working fluid is changed from the gas phase to the liquid phase after the temperature is reduced. After that, the working fluid is circulated back to the first space (11B) of the evaporation unit (1B) through the second pipe (32B) to continue to dissipate heat. After receiving the thermal energy, the second partitions (22B) conduct the thermal energy to the heat dissipation fins (28B) on the outer periphery of the condensation unit (2B) to perform heat exchange with relatively low-temperature outside air, thereby completing the heat dissipation of the heat source (C).

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A PCM (phase change material)-based heat sink structure, comprising:
an evaporation unit, having a sealed first space therein, the first space being provided with a plurality of spaced first partitions that are integrally formed by an aluminum extrusion process, the first partitions partitioning the first space into a plurality of first branch passages, the first partitions being formed with a first main passage, the first main passage being in communication with each of the first branch passages;
a condensation unit, the condensation unit and the evaporation unit forming a circulating heat dissipation loop, the condensation unit having a sealed second space therein, the second space being provided with a plurality of spaced second partitions that are integrally formed by an aluminum extrusion process, the second partitions partitioning the second space into a plurality of second branch passages, the second partitions being formed with a second main passage, the second main passage being in communication with each of the second branch passages, an outer periphery of the condensation unit being provided with at least one heat dissipation fin;
a connecting pipe, including at least one first pipe and at least one second pipe, the first pipe having a first end passing through the evaporation unit and communicating with the first space and a second end passing through the condensation unit and communicating with the second space, the second pipe having a third end passing through the evaporation unit and communicating with the first space and a fourth end passing through the condensation unit and communicating with the second space.

2. The PCM-based heat sink structure as claimed in claim 1, wherein a periphery of the evaporation unit is formed with a first opening and a second opening opposite to the first opening, the first opening and the second opening are in communication with the first space, the first opening is sealed with a first cover and the second opening is sealed with a second cover, thereby sealing the first space.

3. The PCM-based heat sink structure as claimed in claim 2, wherein the first cover is provided with an injection end, the first space and the second space are exhausted to be in a vacuum state through the injection end and sealed after being filled with a working fluid, and the third end passes through the second cover and communicates with the first branch passages.

4. The PCM-based heat sink structure as claimed in claim 1, wherein a periphery of the condensation unit is formed with a third opening and a fourth opening opposite to the third opening, the third opening and the fourth opening are in communication with the second space, the third opening is sealed with a third cover and the fourth opening is sealed with a fourth cover, thereby sealing the second space, the second end passes through the fourth cover and communicates with the second branch passages, and the fourth end passes through the third cover and communicates with the second branch passages.

5. The PCM-based heat sink structure as claimed in claim 1, wherein a periphery of the evaporation unit is formed with a first processing port communicating with the first space, the first processing port corresponds in position to middle portions of the first partitions, through the first processing port, the middle portions of the first partitions are formed with the first main passage by a milling process, and the first processing port is sealed with a first shield, thereby sealing the first space.

6. The PCM-based heat sink structure as claimed in claim 5, wherein the periphery of the evaporation unit is formed with a first opening and a second opening opposite to the first opening, the first opening and the second opening are in communication with the first space, the first opening is sealed with a first cover and the second opening is sealed with a second cover, thereby sealing the first space.

7. The PCM-based heat sink structure as claimed in claim 6, wherein the first cover is provided with an injection end, the first space and the second space are exhausted to be in a vacuum state through the injection end and sealed after being filled with a working fluid, and the third end passes through the second cover and communicates with the first branch passages.

8. The PCM-based heat sink structure as claimed in claim 5, wherein a periphery of the condensation unit is formed with a third opening and a fourth opening opposite to the third opening, the third opening and the fourth opening are in communication with the second space, the third opening is sealed with a third cover and the fourth opening is sealed with a fourth cover, thereby sealing the second space, the second end passes through the fourth cover and communicates with the second branch passages, and the fourth end passes through the third cover and communicates with the second branch passages.

9. The PCM-based heat sink structure as claimed in claim 1, wherein a periphery of the condensation unit is formed with a second processing port communicating with the second space, the second processing port corresponds in position to middle portions of the second partitions, through the second processing port, the middle portions of the second partitions are formed with the second main passage by a milling process, and the second processing port is sealed with a second shield, thereby sealing the second space.

10. The PCM-based heat sink structure as claimed in claim 9, wherein a periphery of the evaporation unit is formed with a first opening and a second opening opposite to the first opening, the first opening and the second opening are in communication with the first space, the first opening is sealed with a first cover and the second opening is sealed with a second cover, thereby sealing the first space.

11. The PCM-based heat sink structure as claimed in claim 9, wherein the periphery of the condensation unit is formed with a third opening and a fourth opening opposite to the third opening, the third opening and the fourth opening are in communication with the second space, the third opening is sealed with a third cover and the fourth opening is sealed with a fourth cover, thereby sealing the second space, the second end passes through the fourth cover and communicates with the second branch passages, and the fourth end passes through the third cover and communicates with the second branch passages.

12. The PCM-based heat sink structure as claimed in claim 1, wherein one side of an outer periphery of the evaporation unit, corresponding in position to middle portions of the first partitions, is formed with the first main passage by a drilling process, and the first end is in communication with the first main passage.

13. The PCM-based heat sink structure as claimed in claim 12, wherein a periphery of the evaporation unit is formed with a first opening and a second opening opposite to the first opening, the first opening and the second opening are in communication with the first space, the first opening is sealed with a first cover and the second opening is sealed with a second cover, thereby sealing the first space.

14. The PCM-based heat sink structure as claimed in claim 12, wherein a periphery of the condensation unit is formed with a third opening and a fourth opening opposite to the third opening, the third opening and the fourth opening are in communication with the second space, the third opening is sealed with a third cover and the fourth opening is sealed with a fourth cover, thereby sealing the second space, the second end passes through the fourth cover and communicates with the second branch passages, and the fourth end passes through the third cover and communicates with the second branch passages.

15. The PCM-based heat sink structure as claimed in claim 1, wherein middle portions of the second partitions are formed with the second main passage.

16. The PCM-based heat sink structure as claimed in claim 15, wherein a periphery of the evaporation unit is formed with a first opening and a second opening opposite to the first opening, the first opening and the second opening are in communication with the first space, the first opening is sealed with a first cover and the second opening is sealed with a second cover, thereby sealing the first space.

17. The PCM-based heat sink structure as claimed in claim 15, wherein a periphery of the condensation unit is formed with a third opening and a fourth opening opposite to the third opening, the third opening and the fourth opening are in communication with the second space, the third opening is sealed with a third cover and the fourth opening is sealed with a fourth cover, thereby sealing the second space, the second end passes through the fourth cover and communicates with the second branch passages, and the fourth end passes through the third cover and communicates with the second branch passages.

18. The PCM-based heat sink structure as claimed in claim 1, wherein one side of the outer periphery of the condensation unit, corresponding in position to middle portions of the second partitions, is formed with the second main passage by a drilling process, and the second end is in communication with the second main passage.

19. The PCM-based heat sink structure as claimed in claim 18, wherein a periphery of the evaporation unit is formed with a first opening and a second opening opposite to the first opening, the first opening and the second opening are in communication with the first space, the first opening is sealed with a first cover and the second opening is sealed with a second cover, thereby sealing the first space.

20. The PCM-based heat sink structure as claimed in claim 1, wherein the first pipe has a total cross-sectional area greater than that of the second pipe.
